(19) United States
(12) Patent Application Publication
(10) Pub. No.: US 2022/0345528 A1
(43) Pub. Date: Oct. 27, 2022

(54) HIGH VOLTAGE POWER USAGE METER

(71) Applicant: FOREMAN IP, Sarasota, FL (US)

(72) Inventors: Aaron FOREMAN, Sarasota, FL (US); Frank CRUZ, Garden Grove, CA (US)

(73) Assignee: FOREMAN IP, Sarasota, FL (US)

(21) Appl. No.: 17/726,856

(22) Filed: Apr. 22, 2022

Related U.S. Application Data
(60) Provisional application No. 63/178,111, filed on Apr. 22, 2021.

(51) Int. Cl. H04L 67/12; H04Q 9/00; G01S 19/01; G01R 22/06

(52) U.S. Cl. CPC H04L 67/12; H04Q 9/00; G01S 19/01; G01R 22/06; H04Q 2209/60

(57) ABSTRACT

A high power usage meter connects to a high power generator and a load, or splitter, to allow remote data gathering for use within a system that provides improved functionality. The high power usage meter includes a plurality of AC sensors, a main unit, and a battery. It provides actionable real-time AC power data. Usage of the AC data is logged. Data having parameters derived from the measured AC current or AC voltage is generated and provided within the system. Information from the high power usage meter includes location parameters, such as longitude, latitude, and altitude.

This application claims priority to U.S. Provisional Application Ser. No. 63/178,111 filed on Apr. 22, 2021, which is hereby incorporated by reference into the present application.

### FIELD OF THE INVENTION

The present invention relates to a high voltage power usage meter for use with a device or component, either as a stand-alone meter or connected with other meters.

### SUMMARY OF THE INVENTION

A high power usage meter is disclosed. The high power usage meter includes four AC sensors to detect an AC current or an AC voltage being delivered by a high power generator. The high power usage meter also includes a plurality of shielded cables to connect to the high power generator and a splitter. The high power usage meter also includes a main unit connected to the four AC sensors. The main unit is configured to derive parameters from the detected AC current or AC voltage. The high power usage meter also includes a transceiver on the main unit to communicate with components in a network and provide parameters in data packets. The high power usage meter also includes a GPS to provide location data including an altitude parameter to the data packet.

A method for providing information regarding power usage from a high power generator is disclosed. The method includes detecting an AC current or an AC voltage using four AC sensors of a high power usage meter. The method also includes deriving parameters from the AC current or the AC voltage using a processor of a main unit of the high power usage meter. The method also includes compiling a data packet of the AC current, the AC voltage, the parameters including a location parameter and an altitude parameter, wherein the location parameter is provided from a GPS component. The method also includes sending the data packet from the high power usage meter using a transceiver to a cloud-based server.

A high power usage meter is disclosed. The high power usage meter includes a plurality of AC sensors to detect an AC current and an AC voltage being delivered by a high power generator. The high power usage meter also includes a plurality of shielded cables to connect the high power generator and to a load. The high power usage meter also includes a main unit connected to the plurality of AC sensors. The main unit is configured to derive parameters from the detected AC current or the AC voltage. The high power usage meter also includes a transceiver on the main unit to communicate with a server in a network and to provide the parameters. The high power usage meter also includes a housing to partially enclose the plurality of shielded cables, the main unit, and the plurality of AC sensors.

### BRIEF DESCRIPTION OF THE DRAWINGS

Various other features and attendant advantages of the present invention will be more fully appreciated when considered in conjunction with the accompanying drawings.

FIG. 1 illustrates a block diagram of a remote power usage meter according to the disclosed embodiments.

FIG. 2 illustrates a block diagram of an AC power meter according to the disclosed embodiments.

FIG. 3 illustrates a block diagram of a remote power usage meter connected to a cable according to the disclosed embodiments.

FIG. 4A illustrates a block diagram of AC sensed data from the AC sensors according to the disclosed embodiments.

FIG. 4B illustrates a block diagram of a data packet according to the disclosed embodiments.

FIG. 5 illustrates a power system using remote power usage meters and AC power meters according to the disclosed embodiments.

FIG. 6 illustrates a high power usage meter according to the disclosed embodiments.

FIG. 7 illustrates a system configured to use the high power usage meter according to the disclosed embodiments.

FIG. 8 illustrates an exploded perspective view of a housing for use within the high power usage meter according to the disclosed embodiments.

FIG. 9 illustrates front elevation view of the housing with cables to determine parameters regarding power usage according to the disclosed embodiments.

### DETAILED DESCRIPTION OF THE PREFERRED EMBODIMENTS

Reference will now be made in detail to specific embodiments of the present invention. Examples of these embodiments are illustrated in the accompanying drawings. Numerous specific details are set forth in order to provide a thorough understanding of the present invention. While the embodiments will be described in conjunction with the drawings, it will be understood that the following description is not intended to limit the present invention to any one embodiment. On the contrary, the following description is intended to cover alternatives, modifications, and equivalents as may be included within the spirit and scope of the appended claims. Numerous specific details are set forth in order to provide a thorough understanding of the present invention.

The disclosed embodiments include a universal remote power usage meter that is a self-contained device intended to provide actionable real time alternating current (AC) power data. The disclosed embodiments log the usage of the AC data using different techniques and report these data packets wirelessly to a back end. These reports may be available on request of a given schedule. The usage data may be available for retrieval using known methods.

AC current and AC voltage may be measured physically using sensors connected physically or electrically to the wires. The following parameters may be derived from these measurements:
Power/h 0 to 22000 W;
Energy/h in Joules;
Power Factor 0 to 1 PF;
Frequency 55 to 65 Hz;
Daily AC Current or Amps/Day; and
Daily AC Voltage or Volts/Day.

This information is gathered at the disclosed device and reported to a server. Intelligent processing is available at the server to make decisions based on the received information. The disclosed embodiments may take action regarding the connected generator or device based on the information. The received information may guide different actions. Further, reports may be generated as needed regarding the collected information. The reports may be generated at a specified time or date, or when a threshold is met.

The universal power usage meter records current and voltage utilizing a three channel sensor board and dedicated AC voltage (VAC) circuitry. Special miniature components are used to inductively sense amperage use. The disclosed embodiments may use devices having 1 amp to 75 amps AC of detection. VAC is obtained by the sensor board discrete connections to neutral and phase A for 120 or phase B and phase C for 240 VAC. Special isolation circuitry and other components will be used to avoid arcing and electrical issues. Special firmware exists to decode the signals from the sensor board and properly packetize and broadcast the information to the network.

Communication to the transceiver is carried out internally. The VAC decoder is built on the same board with the microprocessors handling the measurements and data transfer. Special firmware may be developed to complete the hardware system. The disclosed embodiments may use a micro transceiver to reduce size and power consumption. System communications with the transceiver may use standard ASCII protocol at 9600 KB. The main power supply for the system will be integrated inside the inductive board and feed 5 VDC to the main transceiver.

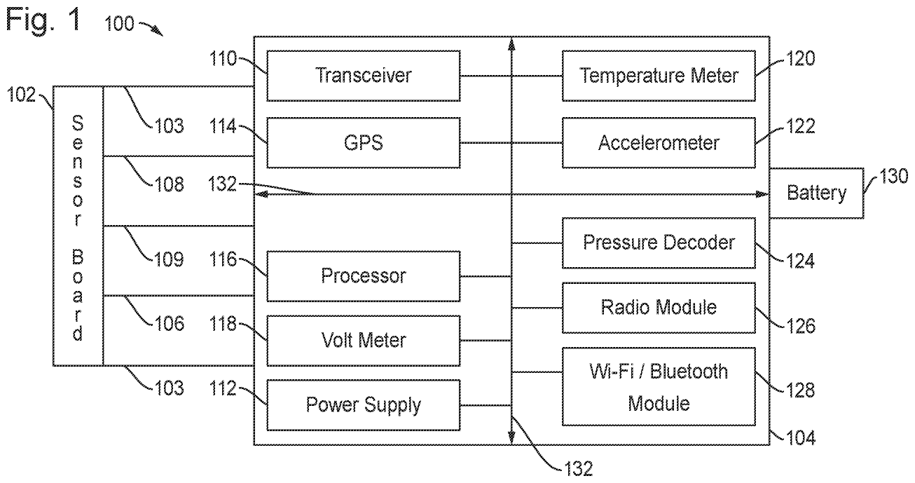

FIG. 1 depicts a block diagram of a remote power usage meter 100 according to the disclosed embodiments. More detailed figures are disclosed below. FIG. 1 illustrates various components of power usage meter 100. As noted above, these components will measure the AC current and AC voltage flowing through a cable connected to equipment, such as a generator that supplies power to other devices. In some embodiments, meter 100 may be referred to as a device.

Power usage meter 100 may have the following specifications. It may have a working voltage of 90 to 260 VAC and a test voltage of 80 to 280 VAC. It also may have a rated measured range of 100 A or 22000 watts. Power usage meter 100 may have an operating frequency of 55 to 65 Hz. It also may have a measurement accuracy of 2.0%. The power usage meter may communicate over known networks, such as 4G and 5G, as well as wi-fi, BLUETOOTH™, radio, cellular, and the like platforms. Power usage meter 100 also includes an integrated variable power supply regulated 5 VDC output. The disclosed meter also does not have any moving or special parts. Connection to a cable end is seamless and simple.

Sensor board 102 is connected to main unit 104, which is also coupled to battery 130. Battery 130 may be a backup battery to maintain power within power usage meter 100. Battery 130 may provide 3.7 VDC to main unit 104. Sensor board 102 is connected to main unit 104 using socket connection 103. Socket connection 103 may house wires 106, 108, and 109. Wire 106 may provide the AC data to main unit 104 while wires 108 and 109 may provide 90 to 160 VAC. Sensor board 102 includes three AC inductive sensors to provide the data.

Main unit, or processing board, 104 may include the primary components for power usage meter 100. These components are listed below then disclosed in greater detail by other figures. The components may be connected within main unit 104 by bus 132. Main unit 104 itself may have a heavy duty fire-proof connector body to attach to a cable. It also may implement a multiconductor shielded cable for interconnection.

Transceiver 110 may exchange data via a network with other components, such as a backend server that provides the decision and intelligence functionality of taking actions based on the information provided by power usage meter 100. In some embodiments, transceiver 110 operates over a 4G or 5G network. Main unit 104 also may include radio module 126 and wi-fi/BLUETOOTH module 128, which communicate over different networks than transceiver 110. Alternatively, modules 126 and 128 may be incorporated into transceiver 110.

High precision global positioning system (GPS) 114 provides augmented location accuracy of power usage meter 100. GPS 114 may provide longitude and latitude location information. It also may provide altitude or elevation information in that power usage meter 100 may report a height or vertical level of its position. For example, power usage meter 100 may report which floor that it is deployed during an operation. This feature distinguishes multiple power usage meters in a single location being used at various heights. GPS 114 may generate a GPS packet that includes latitude, longitude, altitude, quality, frequency, time, date, and the like.

Power usage meter 100 also includes a high speed VAC three channel data processor 116 for AC measurements. Processor 116 may receive the sensed data from sensor board 102 and determine the further data disclosed above. Processor 116 may receive data from sensor board 102 as data packets.

Variable power converter or power supply 112 may convert the AC voltage passing through the cable to 5 VDC for use within main unit 104. Volt meter 118 also may be used to determine the voltage within main unit 104.

Power usage meter 100 also includes temperature meter 120 and accelerometer 122 as well as barometric pressure decoder 124 to provide further information about the condition of the usage meter. All this generated data may be provided from power usage meter 100 to a server. Power usage meter 100 may use power line communications to provide a signal from processor 116 having location and auxiliary information along with an identification of the meter for upgraded functionality and operations capability.

Power usage meter 100 includes a highly integrated transceiver 110 that replaces the standard sleeve of any type connector, such as a 50 amp twist lock inlet, locking power cord connector. Unique integration is achieved using a replacement sleeve. The sleeve is suitable for all connectors. The disclosed power meter is stealthy and does not require external connections to function. It does not significantly alter the standard connector sleeve dimensions. All connections for power and measurements are internal to meter 100. No external connections are necessary. All connections are made inside the replacement sleeve. The disclosed device also includes a stand-alone telemetry connector part applicable to any extension cable on a site.

Real-time measurements of AC current and voltage may be made to derive watts, power factor (PF), and any number of data points related to measuring AC power utilization. Instant functionality is available once connected. No switches or configurations are required to enable server functionality. A connection to the generator will begin measurement of power used to any tool, appliance, or machine connected to the splitter. The disclosed power usage meter 100 includes a hardwired single shielded cable connection 103 to its sensors to detect AC voltage and current. Power measurements are performed inductively. No physical connection is required for power measurements.

The disclosed devices use sensors on sensor board 102 to obtain the AC current inductively and the AC voltage conducted. The sensors are not obtrusive and do not interfere with the flow of electricity. Sensor board 102 is a double board assembly. The board fits flat against the back of connector 103 and does not change the connector OEM profile or functionality.

AC/DC measurement data is sent over a network, such as 3/4/5G wireless networks, thereby making any local data collection unnecessary. AC measurement data is measured and reported for each of all three circuits independently. Data from power usage meter 100 may be routed to the wireless network, and from there to a cloud-based platform. Data from power usage meter 100 is processed for display or provided in real-time reports.

Battery 130, as disclosed above, is a backup battery to enable management and location of assets attached to the cable having power usage meter 100. Power usage meter 100, however, does not interrupt or serially connect to the high power current normally flowing through the attached cable for power measurements. This feature prevents risk to users or to the connected devices.

The disclosed embodiments also feature AC line communications, or power line communications (PLC). This feature allows communication with connected devices fitted inside all tools and appliances in use for a project. The connected devices are able to determine and report functionality of each piece of equipment receiving power from power usage meter 100. This connection and interaction allows each device connected to the network to measure its internal power use and to determine which power usage meter feeds specific branches or parts of a building or site. The device itself can keep track where it is connected and where else it has been connected in real-time. This allows the disclosed embodiments to report the amount of energy utilized and for how long.

All data reported by power usage meter 100 and any connected device may include time and location along with the exact amount of energy used. It may be broadcasted by each device independently. As soon as the power is shut off, a report may be sent, such as using a the backend server. The reporting schedule may be modified remotely.

The connected devices may include single channel telemetry transceivers installed inside all small and medium AC powered tools and machines connected to the network. The connected devices may use stand-alone telemetry transceivers or as part of the power usage meter transceiver 110 to identify its supply group.

The disclosed embodiments may provide detailed reports to intelligently showcase system health, usage, and economics without user interaction. This feature simplifies the economics of billing while providing a broad view of fleet utilization. Because many of the power usage meters and connected devices may be indoors, the entire branch of the power usage meter and connected devices can communicate their location (latitude/longitude/altitude) to all other devices in the same branch in real-time.

The disclosed embodiments also may utilize two distinct transceivers. A server as part of the system may be integrated into the three-phase 240/480V connector in the wiring from generator(s). Its primary function is to measure all energy outputted from the generator, or house, and report it accordingly. The server also may broadcast uniquely coded PLC packets to help a connected device determine connectivity and power source. It will sense voltage directly, and current inductively.

The connected devices may include an adapter that is manually wired into the downstream device, such as a large fan, to monitor power consumption. It will receive PLC packets from the server nodes to determine its connectivity hierarchy. It also may sense voltage and current directly. The device fitter with an adapter may be moved from branch to branch and will automatically report the unique PLC signature to the branch feeding it.

Power usage meter 100 may be installed on existing cables connected to generators or other devices. The following process may be used to install the disclosed power usage meter. Further, one connects a twist-lock at the end of the disclosed assembly and connect it to the generator's output. Next, one connects the body of the power usage meter to the cable that leads to the splitter spider or to the splitter directly. One ensures that the two twist-lock connectors are locked firmly in place. The connected assembly should be kept away from rain and standing water for the best performance.

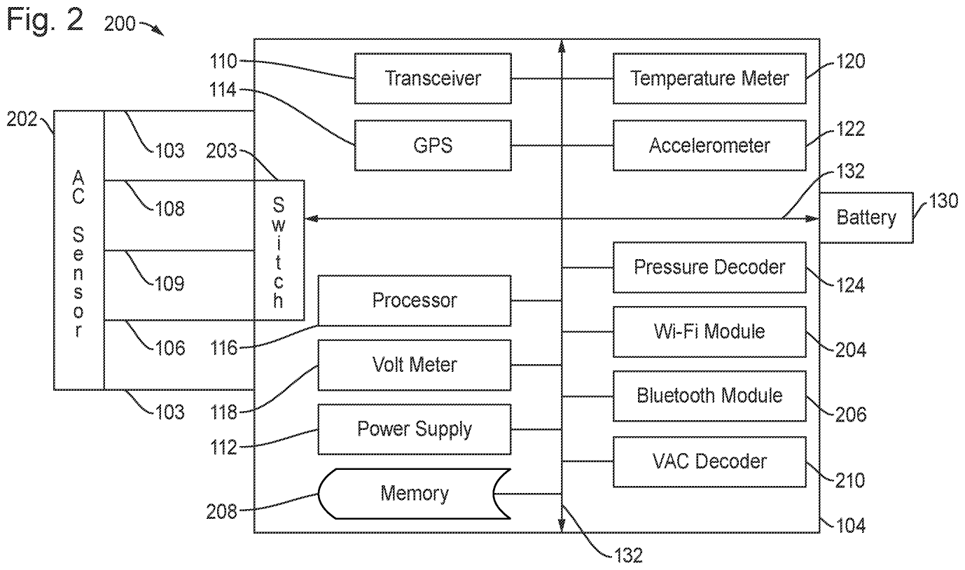

In some embodiments, power usage meter 100 may be used in conjunction with stand-alone AC power meters. FIG. 2 depicts a block diagram of stand-alone AC power meter 200 according to the disclosed embodiments. Some components disclosed in power usage meter 100 also are implemented in AC power meter 200 and not repeated here.

AC power meter 200 is a self-contained industrial device to provide actionable real-time AC power data. The AC power meter may function as a stand-alone AC power meter or as a part of the network with power usage meter 100 illustrated FIG. 1. A back-end server logs the usage of AC data using different techniques and reports these data packets wirelessly to the server. These reports may be available on request on a given schedule. The usage data is available for retrieval from the back end server or accounting software.

AC power meter 200 will measure AC current and AC voltage physically. Using these measurements, the following parameters may be derived using logic and processor 116:
Power/h 0 to 1000 W;
Energy/h in Joules;
Power Factor 0 to 1 PF;
Frequency 55 to 65 Hz;
Daily AC Current or Amps/Day; and
Daily AC Voltage or Volts/Day.

AC power meter 200 may use a unique communication configuration to report these parameters where they are needed or store them in memory 208. AC power meter 200 records AC current and AC voltage using an AC sensor 202, which may include a one channel sensor board and dedicated VAC circuitry. AC sensor 202 also may be a sensor board much like sensor board 102 disclosed above. VAC is obtained by the sensor board, or AC sensor 202, discrete connections to neutral and phase A for 120 VAC. Components and firmware exist in main unit 104 to decode the signals from AC sensor 202 and properly packetize and broadcast the information to a network. The network may be connected to the back end server disclosed above.

Communication to transceiver 110 is carried out internally. VAC decoder 210 is built on the same board with one or more processors 116 handling measurements and data transfer. Special firmware may be implemented to compliment the hardware system of AC power meter 200. This firmware may be disclosed in greater detail below. System communications with transceiver 110 will use standard ASCII protocol at 115000 KB. Main power supply 112 is to be integrated inside main unit 104 and feed 5 VDC to transceiver 110.

AC power meter 200 may have the following specifications. It may have a working voltage of 90 to 140 VAC and a test voltage of 70 to 280 VAC. It also may have a rated measured range of 20 A or 1000 watts. AC power meter 100 may have an operating frequency of 55 to 65 Hz. It also may have a measurement accuracy of 4.0%. The AC power meter may include communication over known networks, such as 4G and 5G, as well as wi-fi, BLUETOOTH™, radio, cellular, and the like platforms. AC power meter 200 also includes an integrated variable power supply regulated 5 VDC output. As disclosed above, it also includes a single AC inductive sensor 202 built according to some embodiments. Wires 106, 108, and 109 feed into load switch 203 of main unit 104. The disclosed meter also does not have any moving or special parts. Connection to a cable end is seamless and simple.

AC power meter 200 includes many of the same components as power usage meter 100 disclosed above with some of the following differences. Transceiver 110 may be an AVL transceiver to communicate over 4G or 5G networks with GPS 36 channels. Power supply 112 may be an AC power supply to convert 140 VAC to 5 VDC. Wi-fi module 204 and BLUETOOTH™ module 206 allow for communications over those protocols. Module 206 may utilize BLUETOOTH™ 2.0/4.2 capabilities.

AC power meter 200 utilizes transceiver 110, which is a highly integrated transceiver, that can be used with any AC device or appliance independently to measure data in real-time. Real-time measurements of AC current and AC voltage may be performed to derive watts, PF, and any number of data points related to measuring AC power utilization. Instant functionality is available upon connection. No switches or special configurations are required to enable the back-end server functionality. One may connect to the ON/OFF switch and begin measuring power used to enable any tool, appliance, machine, and the like connected to the circuit.

AC power meter 200 uses specially designed AC sensor 202 to obtain AAC inductively and VAC conducted. The sensors are not obtrusive and do not interfere with the flow of electricity. AC sensor 202 is a compact multi-layer assembly. The AC/DC measurement data may be sent to a wireless network using 4G or 5G wireless networks. This feature makes unnecessary any local data collection. Data may be routed to a back-end server for accounting purposes. In some embodiments, data may be stored in memory 208 within AC power meter 200 to be collected when it is connected to a network or the back-end server.

AC power meter 200 features AC line communications, or PLC. Communication with multiple AC power meters devices fitted inside tools and appliances is available for inter-communication and reporting. Devices using AC power meter 200 are able to determine and report the functionality being provided at the location as set forth in the received data. Devices may report the amount of energy used and the duration of the power provided therein. All data reported by AC power meter 200 may contain time and location (latitude/longitude/altitude) along with the exact amount of energy used. Reports may be generated asynchronously when the device or appliance is turned ON and OFF.

AC power meter 200 and power usage meter 100 may be over the air programmable in that various operational parameters may be changed using an application or program over the network to the power meter. One does not have to access the AC power meter directly to change functions and operational parameters, such as how often data packets are sent to a back-end server. For example, default mode may be snapshots taken every minute of the power consumption and other parameters for the connected device. The disclosed embodiments may modify this mode to take snapshots every 5 minutes.

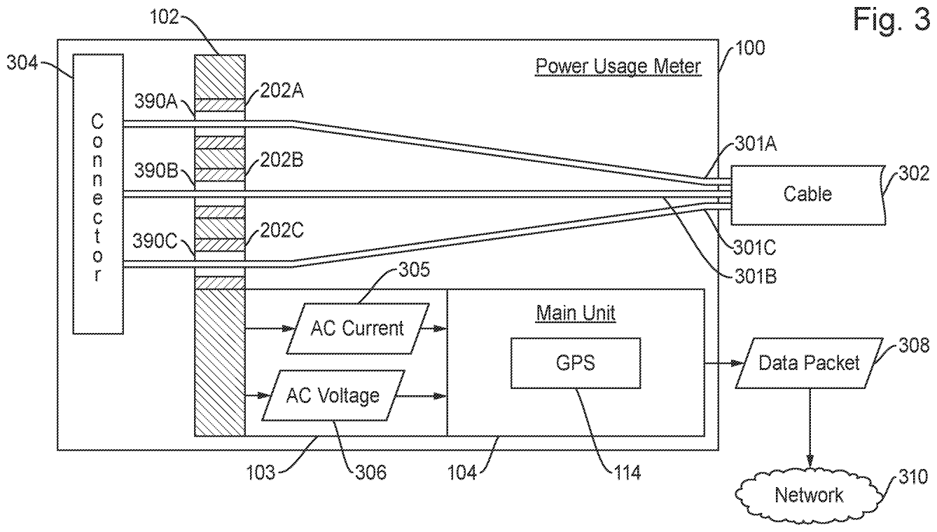

FIG. 3 depicts a block diagram of remote power usage meter 100 connected to cable 302 according to the disclosed embodiments. Power usage meter 100 includes main unit 104, disclosed above. Power usage meter 100 shows AC current data 305 and AC voltage data 306 being provided from sensor board 102 through socket connection 103 to main unit 104. Sensor board 102 includes sensors 202A, 202B, and 202C.

Holes 390A, 390B, and 390C may be placed in sensor board 102 to allow wires 301A, 301B, and 301C to be respectively placed through the sensor board to connector 304. Sensors 202A, 202B, and 202C inductively sense amperage use within wires 301A, 301B, and 301C, respectively. In some embodiments, sensors 202A, 202B, and 202C are inductive sensors. The sensors provide real time measurements of AC current 305 and AC voltage 306 to derive watts, power factor, and any number of data points related to measuring AC power utilization. These measurements are fed to main unit 104 to be paired with data from GPS 114 and sent within network 310.

Sensors 202A, 202B, and 202C are not obtrusive and do not interfere with the flow of signals or power from cable 302 to a powered device. A sensor according to the disclosed embodiments fits within sensor board 102. The sensors may be spaced from each other accordingly, such as in a three point configuration such that wires 301A, 301B, and 301C do not interfere with each other. Another hole 390 may be placed in sensor board 102 for a ground wire from cable 302. Sensor board 102 may be a double board that fits flat against a side of connector 304 so that it does not interfere with the connector OEM profile or functionality.

Main unit 104 may process the AC sensed data, include AC current 305 and AC voltage 306, to generate data packet 308. AC/DC measurement data is measured and reported for each of all three circuits independently. Data packet 308 includes the AC sensed data along with GPS information. Data packet 308 is disclosed in greater detail below. Data packet 308 is sent within network 310 to a server or other collection point for further functionality. Network 310 supports cloud functionality.

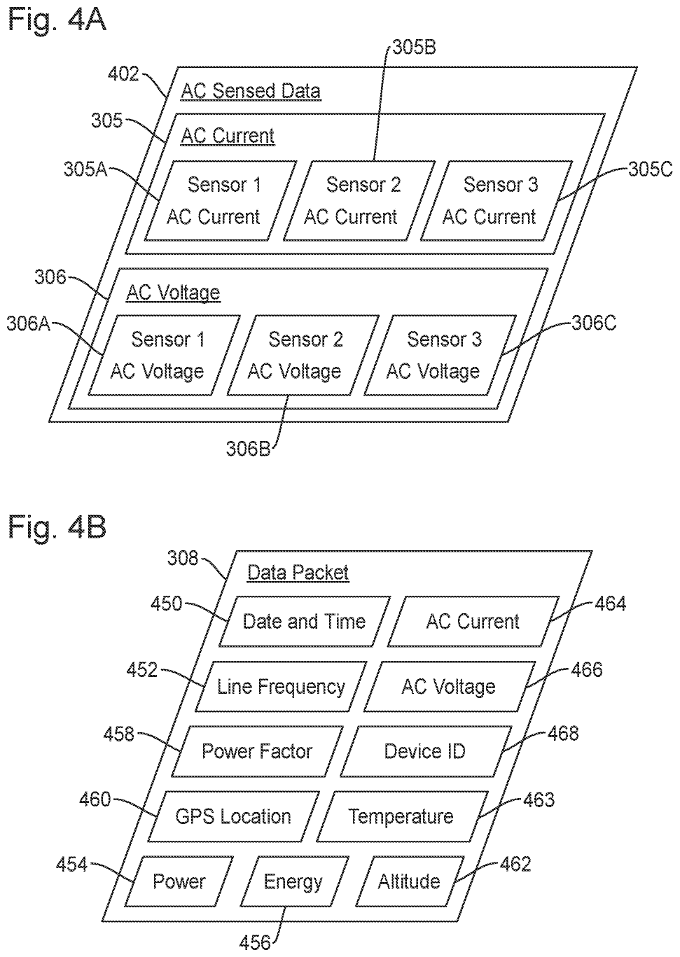

FIG. 4A depicts a block diagram of AC sensed data 402 from the AC sensors according to the disclosed embodiments. Each sensor in sensor board 102 may provide sensed data regarding the AC current and AC voltage present in the respective wire extending through the sensor. For example, at specified times, processor 116 may instruct sensors 202A, 202B, and 202C to take measurements of the AC current and voltage exhibited by wires 301A, 301B, and 301C, respectively. Sensor board 102 collects these measurements and generates AC sensed data 402 to provide to main unit 104.

AC sensed data 402 includes values of AC current 305A for sensor 202A, AC current 305B for sensor 202B, and AC current 305C for sensor 202C. These may be referred to as sensor 1 AC current, sensor 2 AC current, and sensor 3 AC current, respectively. The values may be within AC current 305. AC sensed data 402 also includes values of AC voltage 306A for sensor 202A, AC voltage 306B for sensor 202B, and AC voltage 306C for sensor 202C as part of AC voltage 306. Using these values, main unit 104 may determine other information for the power usage of cable 302.

FIG. 4B depicts a block diagram of a data packet 308 according to the disclosed embodiments. Parameters within data packet 308 may be generated at main unit 104 using information from AC sensed data 402. Further, additional information may be added to data packet 308 by components on main unit 104. Data packet 308 is sent periodically to a cloud based platform to compile and track data regarding energy usage by devices connected to power usage meters 100.

Data packet 308 includes a date and time parameter 450 that indicates the date and time that the data packet is sent. Alternatively, parameter 450 may include the date and time when data packet 308 is created or another specified time, such as when measurements were taken using sensor board 102. Line frequency parameter 452 include the frequency detected for the AC sensed data from cable 302. Power parameter 454 includes the amount of power used per hour, day, minute, and the like, preferably between 0 to 22,000 watts. Energy parameter 456 include the energy used per hour, day, and the like, preferably in Joules. Power factor parameter 458 includes the power factor observed at cable 302, preferably between 0-1 PF. Data packet 308 also includes AC current parameter 464 for the current usage at cable 302. AC current parameter 464 may be the daily current usage, or amps per day. Data packet 308 also includes AC voltage parameter 466 for voltage per day.

Data packet 308 also includes information not related to sensed AC data 402. GPS 114 may provide GPS location data for GPS location parameter 460. GPS 114 is provided on main unit 104. Preferably, GPS 114 is separated from those components on main unit 104 that interfere with the proper determination of the GPS location. When data packet 308 is generated, processor 116 may request GPS data from GPS 114.

Altitude parameter 462 also is provided based on information determined by main unit 104. Altitude information may be important in scenarios where multiple devices are provided in a location, such as an office building. Devices may be placed on different floors of the building, which appear as one device in a location provides by GPS data. These devices, however, differ in their altitude, or placement using a height information. Data packet 308 includes altitude parameter 462 to provide that information to distinguish devices that may be located on top of each other in a building. Accelerometer 122 may be used to determine this information.

Data packet 308 also include temperature parameter 463 derived from temperature meter 120 of the temperature at power usage meter 100 when measurements where taken or when the data packet was generated. It also may include device identification parameter 468 to identify power usage meter 100 within a system of such meters and sensors within network 310.

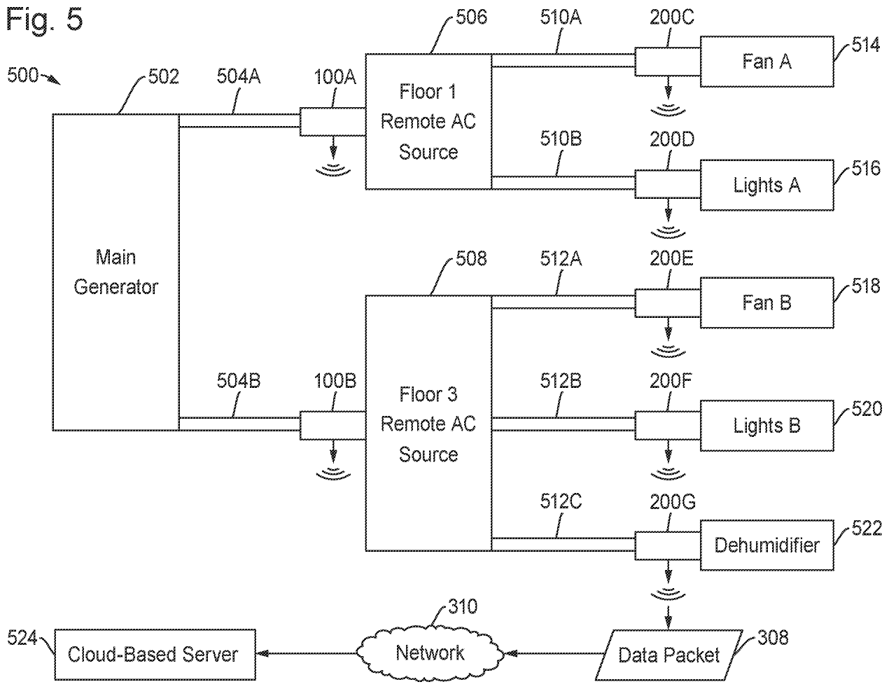

FIG. 5 depicts a power system 500 using remote power usage meters 100A-B and AC power meters 200C-G according to the disclosed embodiments. Power system 500 may illustrate a system of cables, sources, and devices that use power to operate. For example, power system 500 may be used to perform remediation services at a building having multiple floors. Devices, such as fans, lights, and dehumidifiers, may be connected to a main power generator 502. Main power generator 502 may be a street level diesel power generator configured to supply power to devices within the building.

Cable 504A supplies power to floor 1 remote AC source 506. Remote AC source 506 is located on the first floor of the building and supplies power to devices located on that floor, such as fan A 514 and lights A 516. Other devices may be connected to remote AC source 506 but not shown here. Cable 504B supplies power to floor 3 remote AC source 508, which is located on the third floor of the building. Thus, remote AC source 508 may be in the same “location” as remote AC source 506 but on different floors, or at a different altitude. Remote AC source 508 supplies power to devices located on the third floor, such as fan B 518, lights B 520, and dehumidifier 522.

Each remote AC source and device may have an associated power usage meter, similar to power usage meter 100 or AC power meter 200 disclosed above. Accordingly, power usage meter 100A is coupled to cable 504A to measure power supplied to remote AC source 506. Power usage meter 100B is coupled to cable 504B to measure power supplied to remote AC source 508. As disclosed above, power usage meters 100A and 100B may send data packets 308 to cloud-based server 524 over network 310. Data packets 308 may be compiled to determine actual power usage in the remote AC sources as well as determining that the sources are on or off.

The automated reporting of AC power usage as well as location data is used to define the different amounts of power used in the different locations. For example, by using power usage meters 100A and 100B, one may determine where most of the power is being used in remediating the damage within the building. Data may indicate the first floor is using much more power than the third floor. Further, all reporting is done automatically without the need for personnel to check meters or try to guess which devices are using the most power.

Power use data also may be compiled for the different devices attached to the sources within power system 500. For example, AC power meter 200C is coupled to cable 510A that supplies power to fan A 514. AC power meter 200D is coupled to cable 510B that supplies power to lights A 516. AC power meters 200C and 200D also provide data packets 308 to server 524 via network 310 for tracking and monitoring of power usage. The data packets also include location data, such as GPS location parameter 460 and altitude parameter 462, to indicate the location of the devices on the first floor. This data also may indicate if the devices have been moved between power usage reports.

AC power meter 200E is coupled to cable 512A that supplies power to fan B 518. AC power meter 200F is coupled to cable 512B that supplies power to lights B 520. AC power meter 200G is coupled to cable 512C that supplies power to dehumidifier 522. All of these devices may be located on the third floor. The AC power meters also send data packets 308 to server 524 via network 310 for tracking and monitoring of power usage on the third floor of the building.

Thus, the disclosed embodiments may provide power usage data along with other data to a central, cloud-based platform in order to accurately determine power usage within a system. Further, devices may be distinguished from each other using location data. Companies may be able to determine what devices are actually being used and for how long they are being used. This feature results in more accurate tracking and accounting of power usage for large scale projects having many devices without interfering with the operation of the devices or the power supplies attached to the devices.

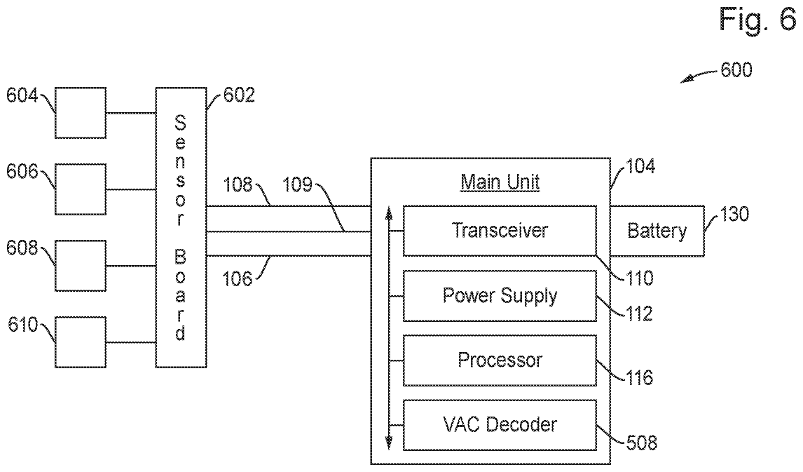

In some embodiments, the remote power usage meter disclosed above may be configured for high power operations. FIG. 6 illustrates a high power usage meter 600 according to the disclosed embodiments. High power usage meter 600 is a self-contained industrial device intended to provide actionable real-time AC power data, much like power usage meter 100 disclosed above. High power usage meter 600 may function as a stand-alone AC power meter or as part of the network with one or more AC power meters 500 disclosed above.

High power usage meter 600 is a three phase, 500 AMP power meter capable of working with 480 ACV in continuous operation. A back-end server, such as cloud-based server 524, logs the usage of AC data using different techniques and reports these data packets wirelessly to the server. These reports may be available on request of a given schedule, much like disclosed above. The usage data generated by high power usage meter 600 may be available for retrieval from the back-end server or accounting software.

As with power usage meter 100, high power usage meter 600 will physically measure AC current and AC voltage. The following parameters may be derived from these measurements:
Power/h 0 to 20000 W;
Energy/h in Joules;
Power Factor 0 to 1 PF;
Frequency 55 to 65 Hz;
Daily AC Current or Amps/Day; and
Daily AC Voltage or Volts/Day.

High power usage meter 600 may have the following specifications, some of which differ from the specifications for power usage meter 100. It may have a working voltage of 120 to 240 VAC and a test voltage of 70 to 280 VAC. It also may have a rated measured range of 500 A or 10000 watts. High power usage meter 600 may have an operating frequency of 55 to 65 Hz. It also may have a measurement accuracy of 5.0%.

High power usage meter 600 may have an IP rating of 65, which indicates that the meter may be used in storm-like conditions such as heavy rain as well as being sealed from dust, light, and water. The high power usage meter may communicate over known networks, such as 4G and 5G, as well as wi-fi, BLUETOOTH™, radio, cellular, and the like platforms. High power usage meter 600 also includes an integrated variable power supply regulated from 240 VAC to 5 VDC output. High power usage meter 600 also includes four AC inductive sensors 604, 606, 608, and 610. Any number of sensors may be used. The disclosed meter also does not have any moving or special parts.

High power usage meter 600 records current and voltage utilizing a custom-made three channel sensor board 602 and dedicated VAC circuitry. The components and circuitry implemented in high power usage meter 600 is disclosed above with regard to power usage meter 100, with some exceptions disclosed below. VAC is detected by discrete connections by sensor board 602 to neutral and phase A/B/C for 240 VAC each, as disclosed below. Firmware according to the disclosed embodiments runs main unit 104 to decode the signals from the multiple sensor boards to properly packetize and broadcast the information to the network.

Communication to transceiver 110 of high power usage meter 600 may be performed internally to each sensor. VAC decoder 508 is implemented in high power usage meter 600 on the same board with one or more processors 116 handling the measurements and data transfer. System communications with transceiver 110 may use standard ASCII protocol at 115000 KB. Main power supply 112 for the system is integrated on main unit 104 with transceiver 110 to feed 5 VDC to the main transceiver.

Components for high power usage meter 600 may correspond to the components disclosed above for power usage meter 100. One difference may be power supply 112 converts 400 VAC to 5 VDC. Other differences may include physical differences, disclosed below.

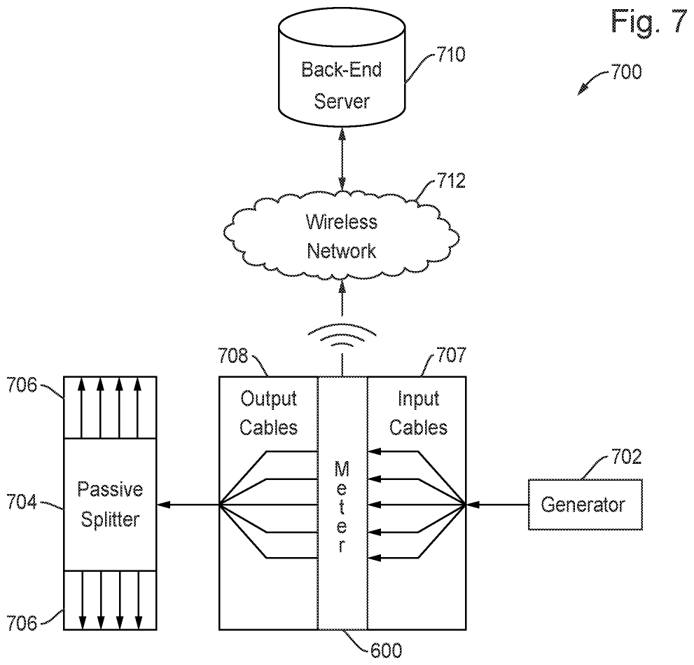

FIG. 7 depicts a system 700 configured to use high power usage meter 600 according to the disclosed embodiments. As can be seen, high power usage meter 600 is connected between a generator 702 that produces power and a passive splitter 704 that connects to direct devices and single power meters, such as power usage meter 100, using power outputs 706. In some embodiments, high power usage meter 600 may be connected to generator 702 and a load.

As disclosed and shown, high power usage meter 600 includes highly integrated transceiver 110 that can be used with high-power generators 702 and any accessories such splitter 704 and cables that connects to a device or appliance independently to measure data in real-time. Real-time measurements of AC current and voltage may be performed, as disclosed above, to derive watts, PF, and any number of data points related to measuring AC power utilization for generator 702. Instant functionality is provided upon connection of high power usage meter 600 to generator 702. No switches or configuration are required to enable the back-end server functionality.

High power usage meter 600 uses specially design sensors 604-610 to obtain the AAC inductively and VAC conducted. Sensors 604-610 are not obtrusive and do not interfere with the flow of electricity between generator 702 and splitter 704 (or any other connected device). The disclosed AC sensor for high power usage meter 600 is a compact, multi-layer assembly, as disclosed below.

AC/DC measurement data is sent to wireless network 712 using 4/5G wireless networks, thereby making it unnecessary to implement local data collection. Data is routed to back-end server 710 for accounting and processing purposes. Back-end server 710 may be similar to cloud-based server 524 disclosed in FIG. 5. All data reported by high power usage meter 600 may contain time and location along with the exact amount of energy used from generator 702. Reports may be generated asynchronously when generator 702 is turned on or off. Parameters and schedule may be programmed over the air or by using a connected device executing an application to communicate with high power usage meter 600.

As shown in FIG. 7, high power usage meter 600 features five cables as input and output. Input cables 707 connect high power usage meter 600 to generator 702 while output cables 708 connect the high power usage meter to splitter 704. Thus, high power usage meter 600 functions in series with the normal cable flow between generator 702 and splitter 704.

High power usage meter 600 may be wired into a downstream device, such as a large fan, to monitor power consumption. Meter 600 will transmit packets containing its identification and location information to downstream AC power meters 500 to determine their connectivity hierarchy and ancillary information to completely augment their transmitted information as they also report power consumption of connected devices.

Input cables 707 and output cables 708 provides the capability to process and analyze high power voltages and currents flowing from generator 702. Cables are used to handle the increased levels of power as opposed to those handled by power usage meter 100 disclosed above. The cables are individually shielded and jacket for each phase or sensor. They are configured to carry 10 times the capacity of power usage meter 100. The number of input cables 707 and output cables 708 may be five, one each for phase 1, phase 2, phase 3, neutral, and ground. The cables may be use with any kind of voltage. Sensor board 602 includes three channel sensor board with a coupling board and the four sensors shown in FIG. 6.

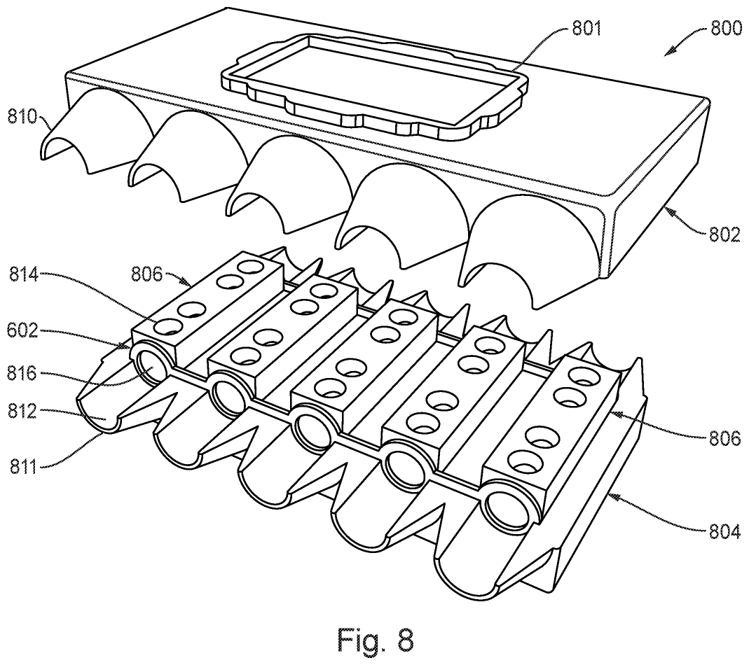

FIG. 8 depicts an exploded perspective view of a housing 800 for use within high power usage meter 100 according to the disclosed embodiments. Housing 800 may be comprised of molded thermoplastic elastomer so as to fit brass bars 806 within channels 812. Input cables 707 and output cables are connected within channels 812 in that an input cable and an output cable is actually a single cable that fits within a brass bar 806.

Housing 800 may comprise two sections, upper section 802 and lower section 804. Upper section 802 includes fitting 801 to secure main unit 104 to housing 800. Main unit 104 sits on top of housing 800 to receive data from the cables partially enclosed by the housing. Upper section 802 includes fitted sections 810, which curve to encompass the cables. The tops of fitted sections 810 taper downwards as they extend away from upper section 802. Lower section 804 includes fitted sections 811 that function the same way as fitted sections 810.

Brass bars 806 sit within channels 812. Brass bars 806 include apertures 814. Each brass bar 806 include through-hole 816 to allow a cable to extend through the brass bar. The bars may be comprised of any material, but brass is preferred as it provides more tensile strength and improved conductivity. Brass bars 806 secure the cables within housing 800 as well as sensor board 602.

Sensor board 602 is fitted to be positioned on each side of brass bars 806. In some embodiments, sensor board 506 is placed on the side of “output” cables 708. In others, another sensor board 602 may be placed on the side of “input” cables 707. Sensor board 602 may act like sensor board 102 disclosed above to sense AC current or AC voltage that flows through each cable that is enclosed by housing 800. Sensor board 602 may sense these parameters without interfering with the operation of the cables from generator 702. Sensor board 602 may feed this data to main unit 104 using sensors 604-610, as disclosed below.

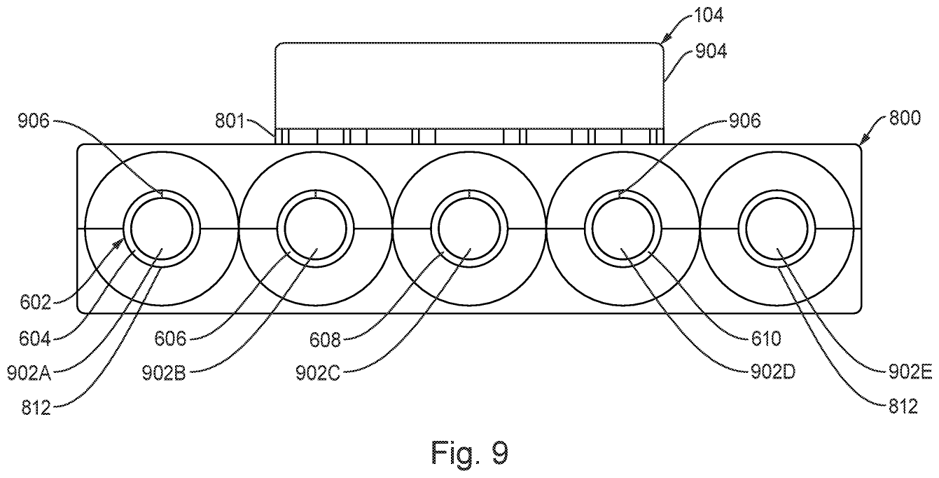

FIG. 9 depicts housing 800 with cables 902A, 902B, 902C, 902D, and 902E to determine parameters regarding power usage according to the disclosed embodiments. Cables 902A-E correspond to input cables 707 and output cables 708. As shown above, these components represent the different sides of the same cable in relation to the generator 702, splitter 704, or load, and high power usage meter 600. An input cable and an output cable, as disclosed above, may be part of the same cable, as shown in FIG. 9.

Each cable represents something different within the system. Cables 902A, 902B, and 902C may be different legs of the three-phase power delivery system from generator 702. The power parameters of these cables may be of interest to main unit 104. Cable 902D may be a neutral cable. Cable 902E may be ground. Cable 902D also may be of interest to main unit 104 whereas cable 902E is not. In other words, main unit does not sense the AC current or AC voltage of cable 902E.

As shown, sensor board 602 includes sensors 604, 606, 608, and 610. These sensors may be shown by the circular portions of sensor board 602 that surrounds each channel 812 within housing 800. Sensor 604 may sense the AC parameters for cable 902A. Sensor 606 may sense the AC parameters for cable 902B. Sensor 608 may sense the AC parameters for cable 902C. Sensor 610 may sense the AC parameters for cable 902D. Cable 902E may not correspond to a sensor as it is the ground cable. The sensors feed the data to main unit 104 for processing, as disclosed above.

Connectors 906 connect to sensors 604-610 on sensor board 602 to provide data to main unit 104. Alternatively, the disclosed embodiments may use the configuration disclosed in FIG. 6. Main unit 104 may be enclosed by upper cover 904, which also may be molded thermoplastic elastomer material, much like housing 800.

It will be apparent to those skilled in the art that various modifications to the disclosed may be made without departing from the spirit or scope of the invention. Thus, it is intended that the present invention covers the modifications and variations disclosed above provided that these changes come within the scope of the claims and their equivalents.

What is claimed is:

1. A high power usage meter comprising:
four AC sensors to detect an AC current or an AC voltage being delivered by a high power generator;
a plurality of shielded cables to connect to the high power generator and a splitter;
a main unit connected to the four AC sensors, wherein the main unit is configured to derive parameters from the detected AC current or AC voltage;
a transceiver on the main unit to communicate with components in a network and provide the parameters in a data packet; and
a GPS to provide location data including altitude to the data packet.

2. The high power usage meter of claim 1, further comprising an accelerometer to provide data to the information.

3. The high power usage meter of claim 1, further comprising a temperature meter to provide data to the information.

4. The high power usage meter of claim 1, further comprising a barometric pressure decoder to provide data to the information.

5. The high power usage meter of claim 1, further comprising a battery to provide power to the main unit.

6. The high power usage meter of claim 1, further comprising a power supply to convert 400 VAC to supply 5 VDC.

7. The high power usage meter of claim 1, further comprising a housing to partially enclose the plurality of shielded cables, the main unit, and the four AC sensors.

8. The high power usage meter of claim 1, wherein the plurality of shielded cables includes five shielded cables.

9. A method for providing information regarding power usage from a high power generator, the method comprising:
detecting an AC current or an AC voltage using four AC sensors of a high power usage meter;
deriving parameters from the AC current or the AC voltage using a processor of a main unit of the high power usage meter;
compiling a data packet of the AC current, AC voltage, the parameters including a location parameter and an altitude parameter, wherein the location parameter is provided from a GPS component; and
sending the data packet from the high power usage meter using a transceiver to a cloud-based server.

10. A high power usage meter comprising:
a plurality of AC sensors to detect an AC current or an AC voltage being delivered by a high power generator;
a plurality of shielded cables to connect to the high power generator and to a load;
a main unit connected to the plurality of AC sensors, wherein the main unit configured to derive parameters from the detected AC current or the AC voltage;
a transceiver on the main unit to communicate with a server in a network and to provide the parameters; and
a housing to partially enclose the plurality of shielded cable, the main unit, and the plurality of AC sensors.

11. The high power usage meter of claim 10, further comprising a GPS to provide a location parameter to the parameters.

12. The high power usage meter of claim 10, further comprising an accelerometer to provide an altitude parameter to the parameters.

13. The high power usage meter of claim 10, further comprising a temperature meter to provide a temperature parameter to the parameters.

14. The high power usage meter of claim 10, further comprising a barometric pressure decoder to provide a barometric parameter.

15. The high power usage meter of claim 10, further comprising sensor board connected to the plurality of AC sensors, wherein the sensor board provides a value for the sensed AC current or the sensed AC voltage to the main unit.
